(19) United States
(12) Patent Application Publication
(10) Pub. No.: US 2004/0211590 A1
(43) Pub. Date: Oct. 28, 2004

(54) Multilayer printed wiring board and integrated circuit using the same

(75) Inventors: Hiroyoshi Tagi, Katano-shi (JP); Seiichi Nakatani, Hirakata-shi (JP); Yoshiyuki Saito, Katano-shi (JP); Takeshi Nakayama, Katano-shi (JP)

Correspondence Address: MERCHANT & GOULD PC, P.O. BOX 2903, MINNEAPOLIS, MN, 55402-0903, US

(73) Assignee: MATSUSHITA ELECTRIC INDUSTRIAL CO., LTD., Kadoma-shi (JP)

(21) Appl. No.: 10/827,924

(22) Filed: Apr. 19, 2004

(30) Foreign Application Priority Data
Apr. 25, 2003 (JP) 2003-122577

(51) Int. Cl. H05K 7/06

(52) U.S. Cl. 174/255; 174/260; 361/780; 361/794; 361/761

(57) ABSTRACT

A multilayer printed wiring board of the present invention includes, e.g., an electrical insulating layer, a plurality of wiring layers arranged alternately with the electrical insulating layer, and a plurality of conductors passing through the electrical insulating layer in its thickness direction for electrically connecting the wiring layers. A plating layer is formed so as to cover the side of the electrical insulating layer and electrically connected to ground wiring. The impedance of a signal transmission conductor arranged in the edge portion of the electrical insulating layer is controlled by a ground conductor arranged opposite to the plating layer with this signal transmission conductor sandwiched between them and the plating layer.

### BACKGROUND OF THE INVENTION

1. Field of the Invention

The present invention relates to a multilayer printed wiring board that includes at least two wiring layers and is used for electronic equipment such as an information processor or radio communication equipment. In particular, the present invention relates to the characteristic impedance control of an inner via, a through hole, or the like for interlayer connection.

2. Description of the Related Art

In recent years, it has been required to increase a signal transmission speed with the progress in high density and high-speed processing of electrical components. The design for a multilayer printed wiring board involves the impedance matching of signal transmission wiring, a through hole or inner via for interlayer connection. This is because such impedance matching suppresses the generation of noise due to reflection or ringing that increases with a rise in signal transmission speed, and thus ensures transmission signal quality. To achieve impedance matching, e.g., a quasi-strip line structure has been employed, in which at least one ground conducting via is arranged on both sides of a signal transmission via. In the quasi-strip line structure, the characteristic impedance is controlled, e.g., by changing a distance between the ground conducting via and the signal transmission via or by changing a diameter of the ground conducting via, so that the impedance matching can be achieved (e.g., JP 2002-232143 A).

FIGS. 6A and 6B show a conventional example of impedance control for a signal transmission via. FIG. 6A is a cross-sectional view of a multilayer printed wiring board, and FIG. 6B is a perspective conceptual diagram for explaining the internal structure of the multilayer printed wiring board. As shown in FIGS. 6A and 6B, the characteristic impedance of a signal transmission via 602 is controlled by a quasi-strip line structure that includes the signal transmission via 602 and ground conducting vias 605 arranged on both sides of the signal transmission via 602. In FIGS. 6A and 6B, reference numeral 606 is ground wiring, 604 is signal transmission wiring, and 603 is an electrical insulating layer.

FIGS. 6C and 6D show a general strip line structure. FIG. 6C is a cross-sectional view, and FIG. 6D is a perspective conceptual diagram. The strip line structure generally includes a transmission line 704 and a pair of ground layers 706 sandwiching the transmission line 704. The pair of ground layers 706 is arranged parallel and symmetrically via an insulator 703. In this strip line structure, the characteristic impedance of the transmission line is controlled by changing a space between the ground layers 706 or a width or thickness of the transmission line 704.

In general, the structure is often determined so that the impedance is matched to 50Ω. In some cases, however, the impedance is matched to 75Ω or 100Ω. For the structure as shown in FIGS. 6A and 6B, the following (a)-(d) may be performed to increase the impedance of the signal transmission via 602.

(a) The distance between the ground wirings is increased.

(b) The cross section of the signal transmission line is made smaller (i.e., the signal transmission via has a smaller diameter).

(c) The pad diameter is made smaller.

(d) The relative dielectric constant of a material for the electrical insulating layer is lowered.

On the other hand, each of the actions in (a)-(d) is reversed to reduce the impedance.

However, a multilayer printed wiring board 601 with the structure as shown in FIGS. 6A and 6B requires that at least one ground conducting via 605 should be formed on both sides of a single signal transmission via 602. The diameter of the ground conducting vias 605 or the distance between the adjacent ground conducting vias 605 has to be set in accordance with a design rule. In the multilayer printed wiring board 601 having the quasi-strip line structure, therefore, the rate (also referred to as “ground occupancy rate” in the following) at which the ground conducting vias 605 and the ground wiring 606 occupy some area in the multilayer printed wiring board 601 is increased. In contrast, the rate at which the signal transmission via 602 and the signal transmission wiring 604 occupy some area in the multilayer printed wiring board 601 is reduced. Thus, the characteristic impedance control using the quasi-strip line structure as shown in FIG. 6B has interfered with increases in density for a multilayer printed wiring board.

### SUMMARY OF THE INVENTION

A multilayer printed wiring board of the present invention includes the following: an electrical insulating layer; a plurality of wiring layers arranged alternately with the electrical insulating layer, each of the wiring layers including ground wiring and signal transmission wiring; a plurality of conductors passing through the electrical insulating layer in the thickness direction of the electrical insulating layer for electrically connecting the wiring layers, the conductors including a signal transmission conductor electrically connected to the signal transmission wiring and a ground conductor electrically connected to the ground wiring; and a plating layer formed so as to cover the side of the electrical insulating layer and electrically connected to the ground wiring. The impedance of the signal transmission conductor arranged in the edge portion of the electrical insulating layer is controlled by the ground conductor arranged opposite to the plating layer with said signal transmission conductor sandwiched therebetween and the plating layer.

Another multilayer printed wiring board of the present invention includes the following: an electrical insulating layer; a plurality of wiring layers arranged alternately with the electrical insulating layer, each of the wiring layers including ground wiring and signal transmission wiring; a plurality of conductors passing through the electrical insulating layer in the thickness direction of the electrical insulating layer for electrically connecting the wiring layers, the conductors including a signal transmission conductor electrically connected to the signal transmission wiring and a ground conductor electrically connected to the ground wiring; a circuit component provided inside the electrical insulating layer; and a plating layer formed so as to cover the side of the electrical insulating layer and electrically connected to the ground wiring. The impedance of the signal transmission conductor arranged in the edge portion of the electrical insulating layer containing the circuit component is controlled by the ground conductor arranged opposite to the plating layer with said signal transmission conductor sandwiched therebetween and the plating layer.

Still another multilayer printed wiring board of the present invention includes the following: a plurality of first electrical insulating layers; a plurality of first wiring layers arranged alternately with the first electrical insulating layers, each of the first wiring layers including first ground wiring and first signal transmission wiring; a plurality of first conductors passing through each of the first electrical insulating layers in the thickness direction of the first electrical insulating layers for electrically connecting the first wiring layers, the first conductors including a first signal transmission conductor electrically connected to the first signal transmission wiring and a first ground conductor electrically connected to the first ground wiring; a circuit component built-in multilayer printed wiring board provided inside any of the first electrical insulating layers; and a first plating layer formed so as to cover the side of the first electrical insulating layers and electrically connected to the first ground wiring. The circuit component built-in multilayer printed wiring board includes the following: a second electrical insulating layer; a plurality of second wiring layers arranged alternately with the second electrical insulating layer, each of the second wiring layers including second ground wiring and second signal transmission wiring; a plurality of second conductors passing through the second electrical insulating layer in the thickness direction of the second electrical insulating layer for electrically connecting the second wiring layers, the second conductors including a second signal transmission conductor electrically connected to the second signal transmission wiring and a second ground conductor electrically connected to the second ground wiring; and a second plating layer formed so as to cover the side of the second electrical insulating layer and electrically connected to the second ground wiring. The impedance of the first signal transmission conductor arranged in the edge portion of the first electrical insulating layer containing the circuit component built-in multilayer printed wiring board is controlled by the second plating layer arranged opposite to the first plating layer with said first signal transmission conductor sandwiched therebetween and the first plating layer.

The present invention easily can suppress the generation of noise due to reflection or ringing while suppressing an increase in the ground occupancy rate of a multilayer printed wiring board and also can achieve higher density of the multilayer printed wiring board. Moreover, the present invention not only can provide more stable grounding than a conventional multilayer printed wiring board with a quasi-strip line structure, but also can suppress ground bounce or the like. Further, EMI (electromagnetic interference) properties can be improved because the plating layer (including the first and second plating layers) also functions as electromagnetic shielding.

### BRIEF DESCRIPTION OF THE DRAWINGS

FIG. 1A is a perspective conceptual diagram of a multilayer printed wiring board of Embodiment 1.

FIG. 1B is a cross-sectional view of the multilayer printed wiring board in FIG. 1A, taken along the line Y-Y′.

FIG. 1C is a perspective conceptual diagram for explaining part of the internal structure of the multilayer printed wiring board in FIG. 1A.

FIG. 1D is another cross-sectional view of the multilayer printed wiring board in FIG. 1A.

FIG. 2A is a cross-sectional view showing an example of a multilayer printed wiring board of Embodiment 2.

FIG. 2B is a perspective conceptual diagram for explaining part of the internal structure of the multilayer printed wiring board in FIG. 2A.

FIG. 2C is another cross-sectional view of the multilayer printed wiring board in FIG. 2A.

FIG. 3A is a cross-sectional view showing an example of a multilayer printed wiring board of Embodiment 3.

FIG. 3B is a cross-sectional view showing an example of a multilayer printed wiring board of Embodiment 3.

FIG. 4A is a cross-sectional view showing an example of a circuit component built-in multilayer printed wiring board that is embedded in a multilayer printed wiring board of Embodiment 4.

FIG. 4B is a cross-sectional view showing an example of a multilayer printed wiring board of Embodiment 4.

FIG. 4C is a perspective conceptual diagram for explaining part of the internal structure of the multilayer printed wiring board in FIG. 4A.

FIG. 5A is a cross-sectional view showing an example of a multilayer printed wiring board of Embodiment 5.

FIG. 5B is a cross-sectional view showing an example of a multilayer printed wiring board of Embodiment 5.

FIG. 6A is a cross-sectional view showing an example of a conventional multilayer printed wiring board.

FIG. 6B is a perspective conceptual diagram of the multilayer printed wiring board in FIG. 6A.

FIG. 6C is a cross-sectional view for explaining a strip line structure.

FIG. 6D is a perspective conceptual diagram for explaining a strip line structure.

### DESCRIPTION OF THE PREFERRED EMBODIMENTS

In a multilayer printed wiring board of this embodiment, the plating layer preferably includes a conductive material having a smaller specific resistance than that of the material for the signal transmission conductor. The conductive material may be at least one selected from, e.g., copper, gold, and silver.

It is preferable that a material layer made of a material having a higher thermal conductivity than that of the material for the electrical insulating layer is formed on the side of the plating layer that faces away from the electrical insulating layer. When the material layer is arranged on the side of the plating layer that faces away from the electrical insulating layer, heat dissipation of the multilayer printed wiring board is improved to the extent that it can be expected to reduce the harmful effect of heat on a semiconductor. Therefore, the multilayer printed wiring board of this embodiment can be applied easily to a heat-dissipating element (circuit component) such as a power circuit or high-frequency circuit.

The material having a higher thermal conductivity may be, e.g., a mixture obtained by mixing inorganic thermal conductive filler such as alumina, silica, beryllia or MgO with an epoxy resin, a phenol resin, an isocyanate resin, or polytetrafluoroethylene. This material preferably includes the inorganic thermal conductive filler in an amount of 70 wt % to 95 wt %.

It is preferable that an electromagnetic shielding layer including a magnetic material and a resin is formed on the side of the plating layer that faces away from the electrical insulating layer. When the electromagnetic shielding layer is formed on the side of the plating layer that faces away from the electrical insulating layer, the EMI characteristics of the multilayer printed wiring board can be improved further.

The magnetic material may be, e.g., ferrite powder. Examples of the resin include an epoxy resin, a phenol resin, an isocyanate resin, and polytetrafluoroethylene. The magnetic material such as ferrite powder accounts for preferably 10 wt % to 95 wt %, and more preferably 50 wt % to 95 wt % of the mixture of the magnetic material and the resin.

In a multilayer printed wiring board containing a circuit component built-in multilayer printed wiring board, it is preferable that the second signal transmission conductor of the circuit component built-in multilayer printed wiring board is arranged in the edge portion of the second electrical insulating layer of the circuit component built-in multilayer printed wiring board, and the second ground conductor of the circuit component built-in multilayer printed wiring board is arranged opposite to the second plating layer with said second signal transmission conductor sandwiched between them.

The impedance of the second signal transmission conductor arranged in the edge portion of the second electrical insulating layer can be controlled by the second ground conductor next to the second signal transmission conductor and the second plating layer. Therefore, the circuit component built-in multilayer printed wiring board can suppress noise generation while suppressing an increase in ground occupancy rate.

A multilayer printed wiring board of this embodiment can be used for an integrated circuit.

Hereinafter, the multilayer printed wiring board of this embodiment will be described more specifically with reference to the drawings.

Embodiment 1

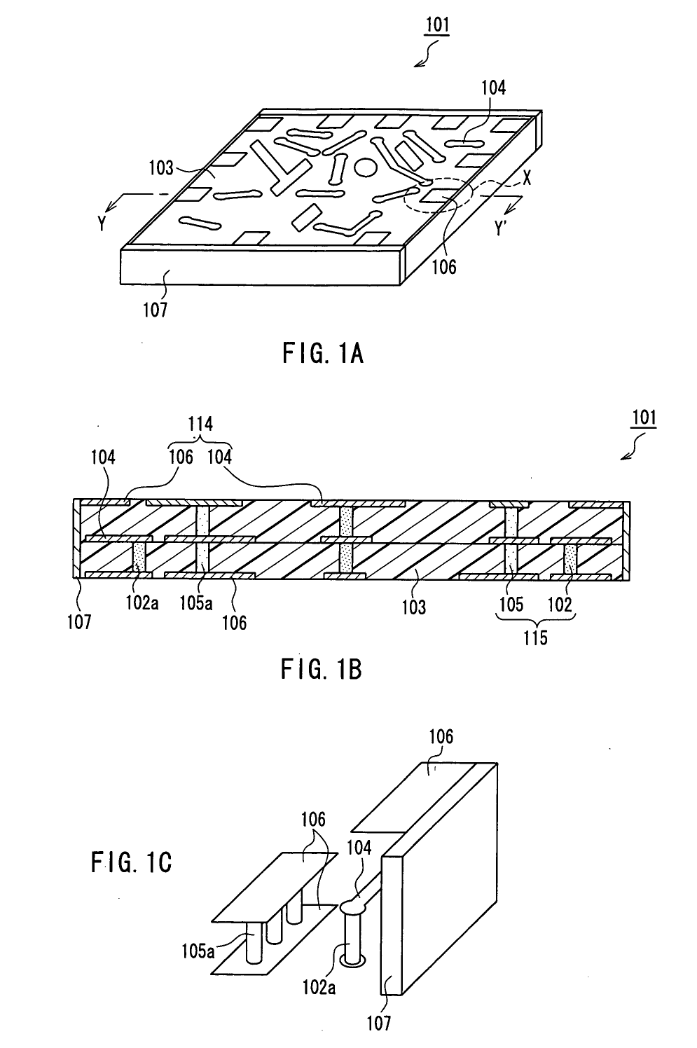

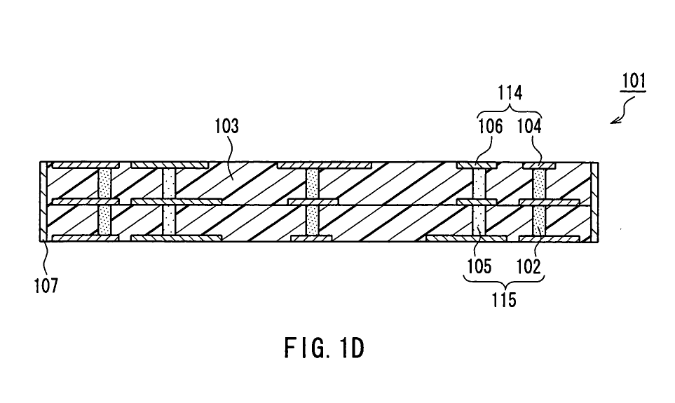

FIGS. 1A to 1D show a multilayer printed wiring board of this embodiment. FIG. 1A is a perspective conceptual diagram. FIG. 1B is a cross-sectional view taken along the line Y-Y′ of FIG. 1A. FIG. 1D is another cross-sectional view. FIG. 1C is a perspective conceptual diagram for explaining part of the internal structure of the multilayer printed wiring board as well as the impedance control structure.

As shown in FIGS. 1A, 1B, and 1D, a multilayer printed wiring board 101 includes a plurality of electrical insulating layers 103, a plurality of wiring layers 114 arranged alternately with the electrical insulating layers 103, and a plurality of conductors 115 passing through each of the electrical insulating layers 103 in their thickness direction for electrically connecting the wiring layers 114. Each of the wiring layers 114 includes ground wiring 106 and signal transmission wiring 104. The conductors 115 include a signal transmission conductor 102 electrically connected to the signal transmission wiring 104 and a ground conductor 105 electrically connected to the ground wiring 106.

A plating layer 107 is formed on the side of the electrical insulating layers 103 and electrically connected to the ground wiring 106.

As shown in FIGS. 1B and 1C, the multilayer printed wring board 101 has the impedance control structure that includes the plating layer 107, a signal transmission conductor 102a arranged in the edge portion of the electrical insulating layer 103, and a ground conductor 105a arranged opposite to the plating layer 107 with the signal transmission conductor 102a sandwiched between them. The signal transmission conductor 102a is the same as the other signal transmission conductors 102, and the ground conductor 105a also is the same as the other ground conductors 105.

As shown in FIG. 1C, the number of ground conductors 105a for constituting the impedance control structure is, e.g., three. The three ground conductors 105a are spaced at a predetermined distance from each other so as to define a plane parallel to the plating layer 107.

Each of the ground conductors 105a is located, e.g., on an extension line that joins the plating layer 107 and the signal transmission conductor 102a. Moreover, on a straight line that joins each of the ground conductors 105a, the signal transmission conductor 102a, and the plating layer 107, e.g., the distance between the signal transmission conductor 102a and the ground conductor 105a is substantially equal to the distance between the plating layer 107 and the signal transmission conductor 102a. The impedance of the signal transmission conductor 102a is controlled by the ground conductors 105a and the plating layer 107.

Unlike the ground conductor, the design of the plating layer 107 is not constrained by the design rule or the like. Therefore, when the multilayer printed wiring board 101 has the impedance control structure (see FIG. 1C) that includes the signal transmission conductor 102a, the plating layer 107, and the ground conductors 105a, it easily can suppress the generation of noise due to reflection or ringing while suppressing an increase in ground occupancy rate, and also can achieve higher density.

Moreover, the ground area of the multilayer printed wiring board 101 is enlarged by the plating layer 107 that is planar and continuous. Thus, the multilayer printed wiring board 101 can achieve more stable grounding than a conventional multilayer printed wiring board with a quasi-strip line structure, and also can suppress ground bounce or the like. Since the plating layer 107 also functions as electromagnetic shielding, the EMI (electromagnetic interference) characteristics of the multilayer printed wiring board 101 can be improved.

The electrical insulating layer 103 can be made of a material obtained, e.g., by mixing inorganic filler with a resin composition that includes an epoxy resin and a curing agent, and curing the mixture while applying heat and pressure with a hot press. The mixture of the resin composition and the inorganic filler includes, e.g., 90 wt % of inorganic filler. Examples of the curing agent include an amine-based curing agent and an acid anhydride-based curing agent.

Any general materials for a printed wiring board can be used as the electrical insulating layer 103, e.g., a glass epoxy material obtained by impregnating glass nonwoven or woven fabric with an epoxy resin or the like, or a material obtained by impregnating a reinforcing material that includes an organic material such as aramid fiber with a resin material.

The multilayer printed wiring board 101, with an emphasis on thermal conductivity, uses a composite that is the mixture of the resin composition (including an epoxy resin and a curing agent) and the inorganic filler and has an inorganic filler content of 90 wt %.

The multilayer printed wiring board 101 in FIGS. 1A to 1D may have the following structure so that the impedance of the signal transmission conductor 102a is matched to 50Ω. The material used for the electrical insulating layer 103 has a relative dielectric constant of, e.g., 3.8. The signal transmission conductor 102a is an inner via with a diameter of, e.g., about 120 μm. The shortest distance between the signal transmission conductor 102a and the ground conductor 105a is, e.g., about 0.25 mm. The shortest distance between the signal transmission conductor 102a and the plating layer 107 is, e.g., about 0.25 mm. The electrical insulating layer 103 has a thickness of, e.g., about 100 μm.

In this embodiment, the diameter of the signal transmission conductor 102a, the distance between the signal transmission conductor 102a and each of the ground conductors 105a, and the distance between the signal transmission conductor 102a and the plating layer 107 are adjusted to provide an appropriate impedance. In addition, the impedance also can be controlled by changing the material for the electrical insulating layer 103, i.e., by changing the relative dielectric constant.

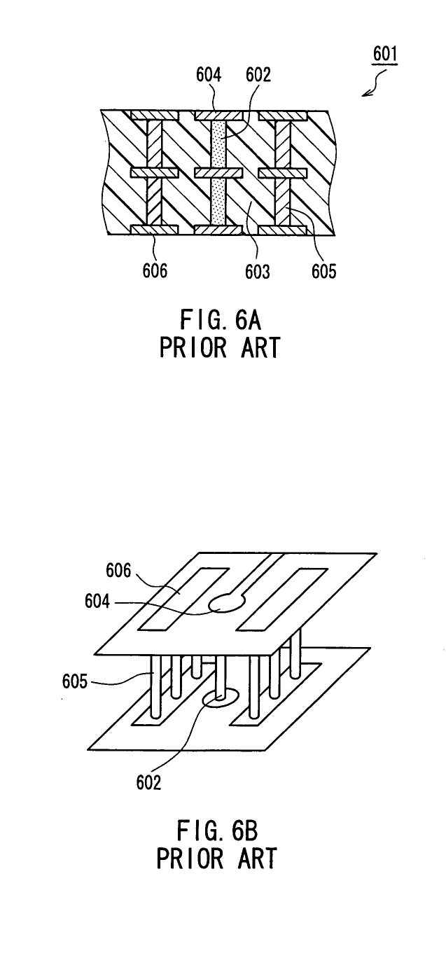

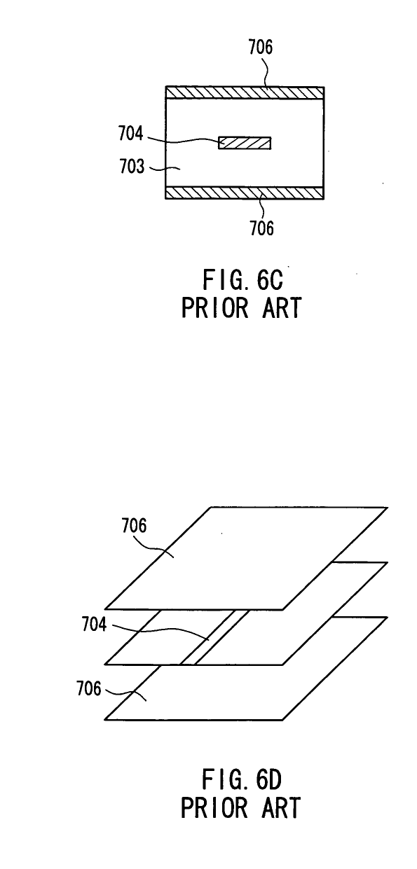

The multilayer printed wiring board 101 was used to simulate the impedance of the signal transmission conductor 102a. The deviation (error) of the impedance from a predetermined value (e.g., 50Ω) was not more than 3%. For a conventional multilayer printed wiring board with a quasi-strip line structure (see FIG. 6B), the deviation (error) of the impedance from a predetermined value (e.g., 50Ω) was at least 5%. Moreover, the EMI noise radiation of the multilayer printed wiring board 101 was reduced due to the plating layer 107 by about 2 dB compared with a conventional multilayer printed wiring board.

Although an electromagnetic wave is radiated in all directions, EMI noise was measured using a TEM cell method (EIA Std. IS-16, etc.) of the U.S. standard. In measuring the EMI noise, an electromagnetic wave was generated by a signal generator having a maximum output of 0 dBm and then input to a power amplifier having a gain of 40 dB, and the output of the power amplifier was input to a TEM cell. In this case, the maximum electric field intensity was 55.9 V/m, the waveform was only unmodulated sine waves, and the frequency was in the range of 150 kHz to 1 GHz.

The plating layer 107 is formed preferably not only on the side, but also on the top and bottom of the electrical insulating layer 103 to achieve a further reduction in EMI noise radiation. In this embodiment, only the side of the electrical insulating layer 103 is provided with the plating layer 107 because circuit components should be arranged on its top and bottom.

Embodiment 2

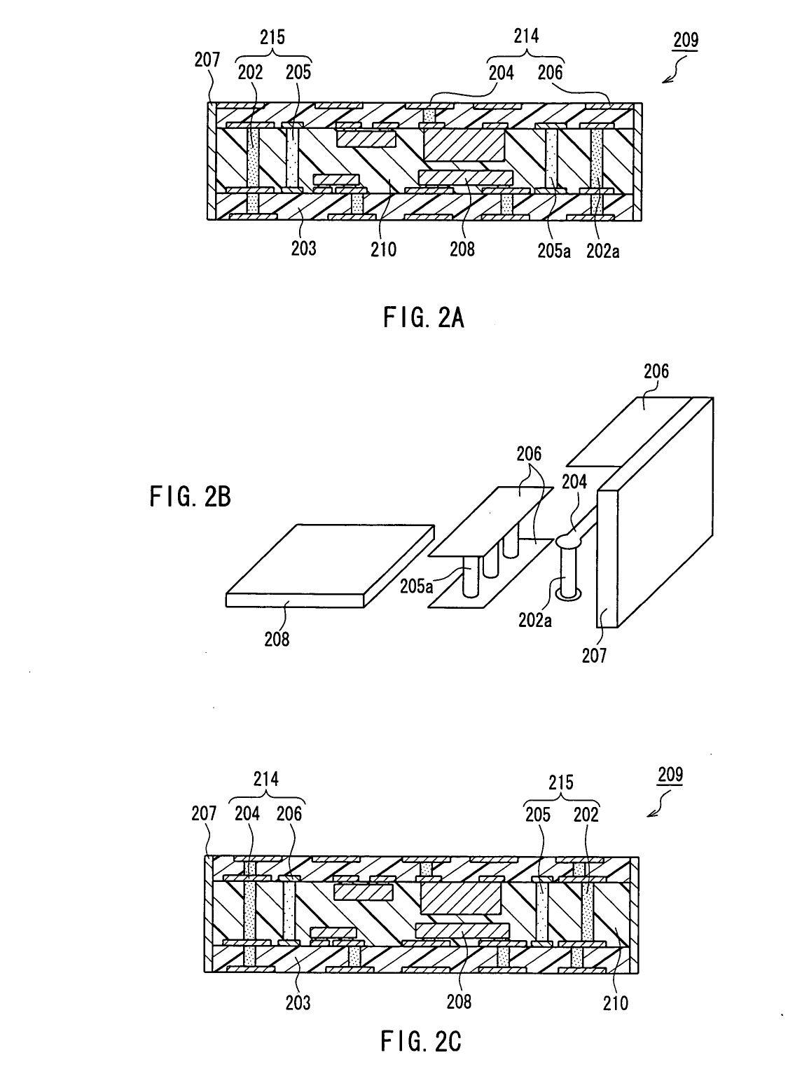

FIGS. 2A to 2C show a multilayer printed wiring board of this embodiment. FIG. 2Ais a cross-sectional view. FIG. 2C is another cross-sectional view. FIG. 2B is a perspective conceptual diagram for explaining part of the internal structure of the multilayer printed wiring board as well as the impedance control structure. The multilayer printed wiring board of this embodiment has an effect comparable to that of the multilayer printed wiring board of Embodiment 1.

As shown in FIGS. 2A and 2C, a multilayer printed wiring board 209 includes a plurality of electrical insulating layers 203, a plurality of wiring layers 214 arranged alternately with the electrical insulating layers 203, a plurality of conductors 215 passing through each of the electrical insulating layers 203 in their thickness direction for electrically connecting the wiring layers 214, and circuit components 208 embedded in any of the electrical insulating layers 203. Each of the wiring layers 214 includes ground wiring 206 and signal transmission wiring 204. The conductors 215 include a signal transmission conductor 202 electrically connected to the signal transmission wiring 204 and a ground conductor 205 electrically connected to the ground wiring 206.

The side of the electrical insulating layers 203 is coated with a plating layer 207, and the plating layer 207 is electrically connected to the ground wiring 206.

In the multilayer printed wiring board 209, any of the electrical insulating layers 203 that contains the circuit components 208 also is referred to as a “circuit component built-in layer 210”, and a signal transmission conductor 202a is arranged in the edge portion of the circuit component built-in layer 210, as shown in FIGS. 2A and 2B. The multilayer printed wiring board 209 has the impedance control structure that includes the plating layer 207, the signal transmission conductor 202a, and a ground conductor 205a arranged opposite to the plating layer 207 with the signal transmission conductor 202a sandwiched between them. The signal transmission conductor 202a is the same as the other signal transmission conductors 202, and the ground conductor 205a also is the same as the other ground conductors 205.

As shown in FIG. 2B, the number of ground conductors 205a for constituting the impedance control structure is, e.g., three. The three ground conductors 205a are spaced at a predetermined distance from each other so as to define a plane parallel to the plating layer 207.

Each of the ground conductors 205a is located, e.g., on an extension line that joins the plating layer 207 and the signal transmission conductor 202a. Moreover, on a straight line that joins the signal transmission conductor 202a, each of the ground conductors 205a, and the plating layer 207, e.g., the distance between the signal transmission conductor 202a and each of the ground conductor 205a is substantially equal to the distance between the plating layer 207 and the signal transmission conductor 202a. The impedance of the signal transmission conductor 202a is controlled by the ground conductors 205a and the plating layer 207.

Unlike the ground conductor, the design of the plating layer 207 is not constrained by the design rule or the like. Therefore, when the multilayer printed wiring board 209 has the impedance control structure (see FIG. 2B) that includes the signal transmission conductor 202a, the plating layer 207, and the ground conductors 205a, it easily can suppress the generation of noise due to reflection or ringing while suppressing an increase in ground occupancy rate, and also can achieve higher density.

As shown in FIGS. 2A and 2C, the signal transmission conductor 202 arranged in the circuit component built-in layer 210 has a long length of, e.g., not less than 0.2 mm. The longer signal transmission conductor 202 is likely to be adversely affected by noise. In the multilayer printed wiring board 209, the impedance of some of the signal transmission conductors 202, particularly of the signal transmission conductor 202 that is likely to be adversely affected by noise is controlled, so that noise generation can be suppressed efficiently without reducing the occupancy rate of the signal transmission conductors 202 and the signal transmission wiring 204.

The multilayer printed wiring board 209 may have the following structure so that the impedance of the signal transmission conductor 202a is matched to 50Ω. The material used for the electrical insulating layer 203 has a relative dielectric constant of, e.g., 3.8. The signal transmission conductor 202a is an inner via with a diameter of, e.g., about 120 μm. The shortest distance between the signal transmission conductor 202a and the ground conductor 205a is, e.g., about 0.25 mm. The shortest distance between the signal transmission conductor 202a and the plating layer 207 is, e.g., about 0.25 mm. The circuit component built-in layer 210 has a thickness of, e.g., 600 μm. The thickness of the other electrical insulating layers 203 is, e.g., 100 μm.

The electrical insulating layer 203 can use the same material as that of the electrical insulating layer of the multilayer printed wiring board in Embodiment 1, e.g., a mixture of inorganic filler (90 wt %) and a resin composition that includes an epoxy resin and a curing agent.

The multilayer printed wiring board 209 was used to simulate the impedance of the signal transmission conductor 202a. The deviation (error) of the impedance from a predetermined value (50Ω) was not more than 3%. Moreover, EMI noise radiation of the multilayer printed wiring board 209 was reduced due to the plating layer 207 by about 6 dB compared with a conventional multilayer printed wiring board with a quasi-strip line structure (see FIG. 6B).

Like Embodiment 1, any general materials for a printed wiring board also can be used to produce the multilayer printed wiring board of this embodiment.

Embodiment 3

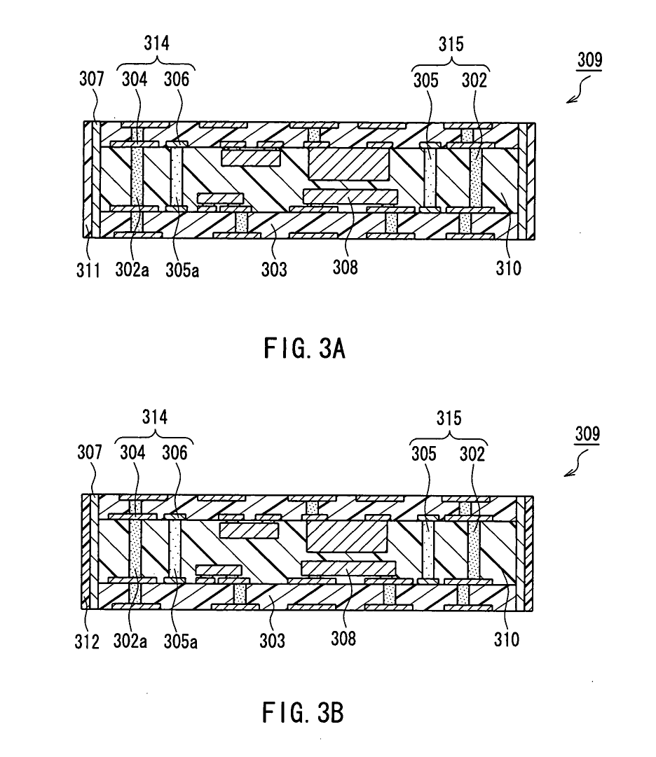

FIGS. 3A and 3B are cross-sectional views of a multilayer printed wiring board of this embodiment. A multilayer printed wiring board 309 in FIG. 3A is the same as Embodiment 2 except that it further includes a material layer 311. A multilayer printed wiring board 309 in FIG. 3B is the same as Embodiment 2 except that it further includes an electromagnetic shielding layer 312. The multilayer printed wiring board of this embodiment has an effect comparable to that of the multilayer printed wiring boards of Embodiments 1 and 2.

As shown in FIGS. 3A and 3B, the multilayer printed wiring board 309 includes a plurality of electrical insulating layers 303, a plurality of wiring layers 314 arranged alternately with the electrical insulating layers 303, a plurality of conductors 315 passing through each of the electrical insulating layers 303 in their thickness direction for electrically connecting the wiring layers 314, and circuit components 308 embedded in any of the electrical insulating layers 303. Each of the wiring layers 314 includes ground wiring 306 and signal transmission wiring 304. The conductors 315 include a signal transmission conductor 302 electrically connected to the signal transmission wiring 304 and a ground conductor 305 electrically connected to the ground wiring 306.

The side of the electrical insulating layers 303 is coated with a plating layer 307, and the plating layer 307 is electrically connected to the ground wiring 306.

In the multilayer printed wiring board 309, any of the electrical insulating layers 303 that contains the circuit components 308 also is referred to as a “circuit component built-in layer 310”, and a signal transmission conductor 302a is arranged in the edge portion of the circuit component built-in layer 310. Like Embodiment 2, the impedance of the signal transmission conductor 302a is controlled by the plating layer 307 and a ground conductor 305a arranged opposite to the plating layer 307 with the signal transmission conductor 302a sandwiched between them. The signal transmission conductor 302a is the same as the other signal transmission conductors 302, and the ground conductor 305a also is the same as the other ground conductors 305.

Like Embodiment 2, the multilayer printed wiring board 309 has the impedance control structure that includes the signal transmission conductor 302a, the plating layer 307, and the ground conductor 305a. Therefore, it is possible to easily suppress the generation of noise due to reflection or ringing while suppressing an increase in ground occupancy rate of the multilayer printed wiring board 309 and to achieve higher density of the multilayer printed wiring board 309.

The multilayer printed wiring board 309 as shown in FIGS. 3A and 3B may have the following structure so that the impedance of the signal transmission conductor 302a is matched to 50Ω. The material used for the electrical insulating layer 303 has a relative dielectric constant of, e.g., 3.8. The signal transmission conductor 302a is an inner via with a diameter of, e.g., about 120 μm. The shortest distance between the signal transmission conductor 302a and the ground conductor 305a is, e.g., about 0.25 mm. The shortest distance between the signal transmission conductor 302a and the plating layer 307 is, e.g., about 0.25 mm. The circuit component built-in layer 310 has a thickness of, e.g., 600 μm, and the signal transmission conductor 302a has a length of 600 μm. The thickness of the other electrical insulating layers 303 is, e.g., 100 μm.

The electrical insulating layer 303 can use the same material as that of the electrical insulating layer of the multilayer printed wiring board in Embodiment 1, e.g., a mixture of inorganic filler (90 wt %) and a resin composition that includes an epoxy resin and a curing agent.

In the multilayer printed wiring board 309 in FIG. 3A, a material layer 311 is formed on the side of the plating layer 307 that faces away from the electrical insulating layer 303. The material layer 311 includes a material having a higher thermal conductivity than that of the material for the electrical insulating layer 303. When the material layer 311 is arranged on the side of the plating layer 307 that faces away from the electrical insulating layer 303, heat dissipation of the multilayer printed wiring board 309 is improved to the extent that it can be expected to reduce the harmful effect of heat on a semiconductor. Therefore, the multilayer printed wiring board 309 can be applied easily to a heat-dissipating element (circuit component) such as a power circuit or the like.

The material having a higher thermal conductivity may be, e.g., a mixture of an epoxy resin and alumina powder. The mixture includes, e.g., 95 wt % of alumina powder. The material layer has a thickness of, e.g., about 20 μm in view of high density, although the heat dissipation increases as the material layer becomes thicker.

In the multilayer printed wiring board 309 in FIG. 3A, the deviation (error) of the impedance of the signal transmission conductor 302a from a predetermined value (50Ω) was not more than 3%, as with the case of the multilayer printed wiring board in Embodiment 2. Moreover, the EMI noise radiation of the multilayer printed wiring board 309 was reduced due to the plating layer 307 by about 6 dB compared with a conventional multilayer printed wiring board with a quasi-strip line structure (see FIG. 6B).

In the multilayer printed wiring board 309 in FIG. 3A, the material layer 311 is formed on the side of the plating layer 307 that faces away from the electrical insulating layer 303. Therefore, heat dissipation of the multilayer printed wiring board 309 is improved to the extent that it can be expected to reduce the harmful effect of heat on a semiconductor.

In the multilayer printed wiring board 309 in FIG. 3B, an electromagnetic shielding layer 312 is formed on the side of the plating layer 307 that faces away from the electrical insulating layer 303. The electromagnetic shielding layer 312 includes a magnetic material and a resin. The multilayer printed wiring board 309 in FIG. 3B further improves the EMI characteristics because of the electromagnetic shielding layer 312.

The magnetic material may be, e.g., ferrite powder. Examples of the resin include an epoxy resin, a phenol resin, an isocyanate resin, and a polytetrafluoroethylene resin. The magnetic material such as ferrite powder accounts for preferably 10 wt % to 95 wt %, and more preferably 50 wt % to 95 wt % of the mixture of the magnetic material and the resin. Specifically, a material obtained by mixing a resin composition that includes an epoxy resin and a curing agent with, e.g., 80 wt % of ferrite powder can be used. Examples of the curing agent include an amine-based curing agent and an acid anhydride-based curing agent.

The thicker the electromagnetic shielding layer 312 is, the more the EMI characteristics improve. However, when the electromagnetic shielding layer 312 is too thick, it interferes with high density and increases the weight of the multilayer printed wiring board 309. Therefore, the thickness of the electromagnetic shielding layer 312 is, e.g., 30 μm.

In the multilayer printed wiring board 309 in FIG. 3B, the deviation (error) of the impedance of the signal transmission conductor 302a from a predetermined value (50Ω) was not more than 3%, as with the case of the multilayer printed wiring board in Embodiment 2. Moreover, the analysis showed that the EMI noise radiation of the multilayer printed wiring board 309 was reduced due to the plating layer 307 and the electromagnetic shielding layer 312 by about 6.5 dB compared with a conventional multilayer printed wiring board with a quasi-strip line structure (see FIG. 6B).

Like Embodiment 1, any general materials for a printed wring board also can be used to produce the multilayer printed wiring board of this embodiment.

Embodiment 4

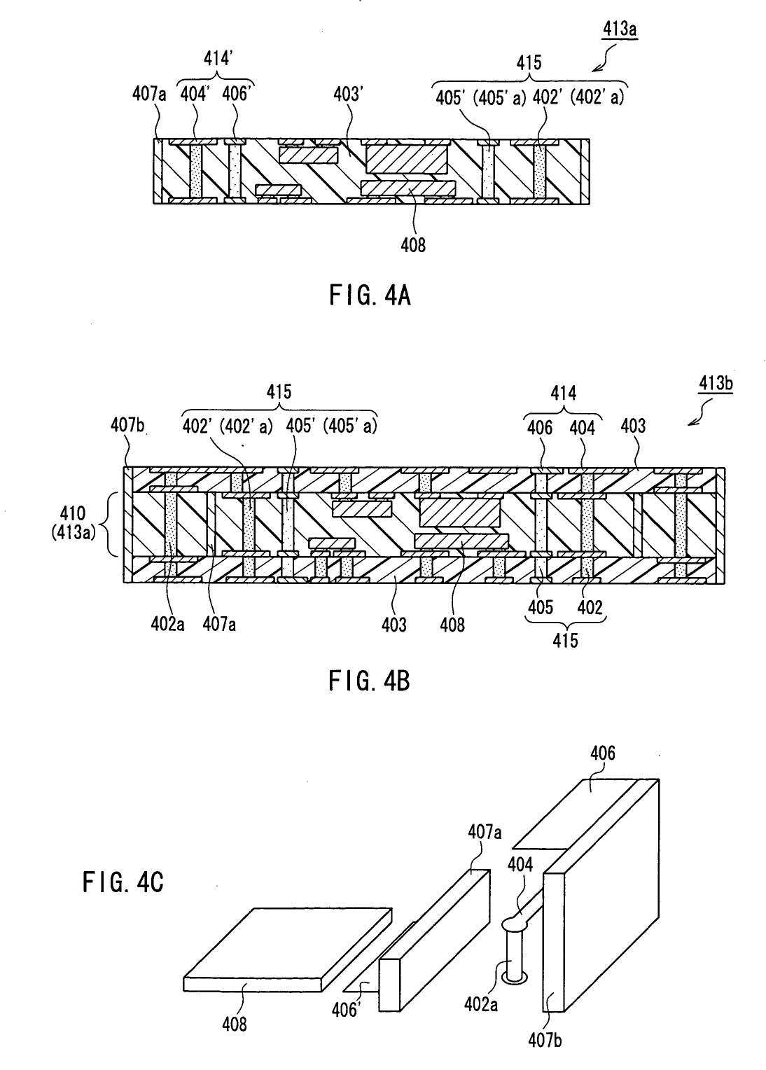

FIG. 4B is a cross-sectional view of a multilayer printed wiring board of this embodiment. FIG. 4A shows a circuit component built-in multilayer printed wiring board that is embedded in the multilayer printed wiring board of this embodiment. The multilayer printed wiring board of this embodiment has an effect comparable to that of the multilayer printed wiring boards of Embodiments 1 to 3.

As shown in FIG. 4B, a multilayer printed wiring board 413b of this embodiment includes a plurality of first electrical insulating layers 403, a plurality of first wiring layers 414 arranged alternately with the first electrical insulating layers 403, and a plurality of first conductors 415 passing through each of the first electrical insulating layers 403 in their thickness direction for electrically connecting the first wiring layers 414. Each of the first wiring layers 414 includes first ground wiring 406 and first signal transmission wiring 404. The first conductors 415 include a first signal transmission conductor 402 electrically connected to the first signal transmission wiring 404 and a first ground conductor 405 electrically connected to the first ground wiring 406.

The side of the first electrical insulating layers 403 is coated with a first plating layer 407b, and the first plating layer 407b is electrically connected to the first ground wiring 406 (see FIG. 4C).

In the multilayer printed wiring board 413b, a circuit component built-in multilayer printed wiring board 413a is arranged inside any of the first electrical insulating layers 403.

As shown in FIG. 4A, the circuit component built-in multilayer printed wiring board 413a includes a second electrical insulating layer 403′, a pair of second wiring layers 414′ arranged alternately with the second electrical insulating layer 403′, a plurality of second conductors 415′ passing through the second electrical insulating layer 403′ in its thickness direction for electrically connecting the pair of second wiring layers 414′, and circuit components 408 provided inside the second electrical insulating layer 403′. Each of the second wiring layers 414′ includes second ground wiring 406′, and second signal transmission wiring 404′. The second conductors 415′ include a second signal transmission conductor 402′ electrically connected to the second signal transmission wiring 404′ and a second ground conductor 405′ electrically connected to the second ground wiring 406′. The second wiring layers 414′ are electrically connected to the first conductors 415, as shown in FIG. 4B.

The side of the second insulating layer 403′ is coated with a second plating layer 407a, and the second plating layer 407a is electrically connected to the second ground wiring 406′ (see FIG. 4C).

Any of the first electrical insulating layers 403 in which the circuit component built-in multilayer printed wiring board 413a is embedded also is referred to as a “circuit component built-in layer 410”, and a first signal transmission conductor 402a is arranged in the edge portion of the circuit component built-in layer 410, i.e., the outside of the circuit component built-in multilayer printed wiring board 413a that is contained in the circuit component built-in layer 410. For example, the second plating layer 407a and the first plating layer 407b are arranged symmetrically and parallel with respect to a central axis of the first signal transmission conductor 402a. The impedance of the first signal transmission conductor 402a is controlled by the first plating layer 407b and the second plating layer 407a.

The first signal transmission conductor 402a is the same as the other first signal transmission conductors 402. The first signal transmission wiring 404, the first ground wiring 406, the first signal transmission conductors 402, and the first ground conductors 405 are the same as the second signal transmission wiring 404′, the second ground wiring 406′, the second signal transmission conductors 402′, and the second ground conductors 405′, respectively.

As described above, the multilayer printed wiring board 413b has the impedance control structure that includes the first signal transmission conductor 402a, the second plating layer 407a, and the first plating layer 407b (see FIG. 4C). Thus, the multilayer printed wiring board 413b does not require a ground conductor (ground conducting via) that has been used to control the impedance of the signal transmission conductor arranged in the edge portion of the electrical insulating layer. The multilayer printed wiring board 413b uses the second plating layer 407a instead of the ground conductor. The ground conductor has a diameter, e.g., in the range of 300 μm to 500 μm, and the ground wiring has a width, e.g., in the range of 120 μm to 250 μm, while the second plating layer has a small thickness, e.g., in the range of 18 μm to 35 μm. Therefore, the use of the second plating layer 407a instead of the ground conductor can increase the occupancy rate of the first signal transmission wiring 404 and the first signal transmission conductors 402 or the occupancy rate of the second signal transmission wiring 404′ and the second signal transmission conductors 402′. Also, noise generation can be suppressed while suppressing an increase in ground occupancy rate. Unlike the ground conductor (ground conducting via), the second plating layer 407a can be planar and continuous. Therefore, the second plating layer 407a, combined with the first plating layer 407b, can provide more stable grounding and further enhance the impedance control accuracy.

As shown in FIG. 4A, it is preferable that a second signal transmission conductor 402′a is arranged in the edge portion of the second electrical insulating layer 403′, and a second ground conductor 405′a is arranged opposite to the second plating layer 407a with the second signal transmission conductor 402′a sandwiched between them. With this configuration, the impedance of the second signal transmission conductor 402′a is controlled by the second plating layer 407a and the second ground conductor 405′a.

When the circuit component built-in multilayer printed wiring board 413a has this impedance control structure, noise generation can be suppressed while suppressing an increase in ground occupancy rate of the circuit component built-in multilayer printed wiring board 413a. The second signal transmission conductor 402′a is the same as the other second signal transmission conductors 402′, and the second ground conductor 405′a is the same as the other second ground conductors 405′.

The multilayer printed wiring board 413b in FIG. 4B may have the following structure so that the impedance of the first signal transmission conductor 402a is matched to 50Ω. The material used for the first and second electrical insulating layers 403, 403′ has a relative dielectric constant of, e.g., 3.8. The first signal transmission conductor 402a is an inner via with a diameter of, e.g., about 120 μm. The shortest distance between the first signal transmission conductor 402a and the second plating layer 407a is, e.g., about 0.25 mm. The shortest distance between the first signal transmission conductor 402a and the first plating layer 407b is, e.g., about 0.25 mm. The circuit component built-in layer 410 has a thickness of, e.g., 600 μm. The thickness of the other electrical insulating layers is, e.g., 100 μm.

In the circuit component built-in multilayer printed wiring board 413a, the second signal transmission conductor 402′a arranged in the edge portion of the second electrical insulating layer 403′ is an inner via with a diameter of, e.g., about 120 μm. The shortest distance between the second signal transmission conductor 402′a and the second ground conductor 405′a is 0.25 mm. The shortest distance between the second signal transmission conductor 402′a and the second plating layer 407a is 0.25 mm.

The first and second electrical insulating layers 403, 403′ can use the same material as that of the electrical insulating layer of the multilayer printed wiring board in Embodiment 1, e.g., a mixture of inorganic filler (90 wt %) and a resin composition that includes an epoxy resin and a curing agent.

Like Embodiment 1, any general materials for a printed wiring board also can be used to produce the multilayer printed wiring board 413b of this embodiment.

The multilayer printed wiring board 413b was used to simulate the impedance of the first signal transmission conductor 402a. The deviation (error) of the impedance from a predetermined value (50Ω) was about 1%. For a conventional multilayer printed wiring board with a quasi-strip line structure (see FIG. 6B), the deviation (error) of the impedance from a predetermined value (e.g., 50Ω) was at least 5%. Moreover, the EMI noise radiation of the multilayer printed wiring board 413b was reduced due to the first plating layer 407b by about 6 dB compared with the conventional multilayer printed wiring board.

Embodiment 5

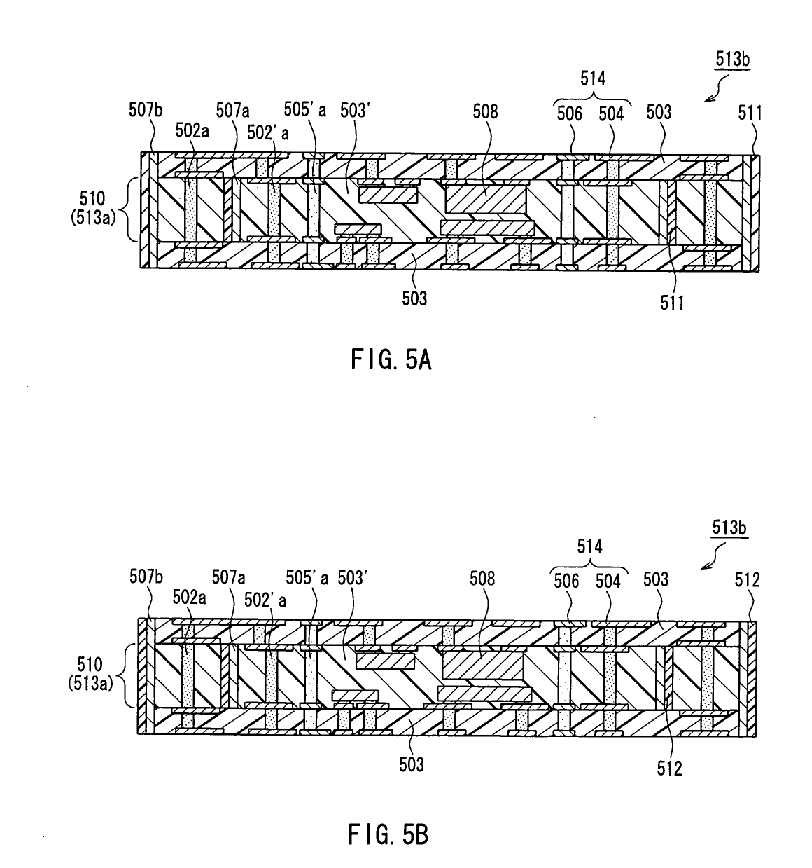

FIGS. 5A and 5B are cross-sectional views of a multilayer printed wiring board of this embodiment. A multilayer printed wiring board 513b in FIG. 5A is the same as Embodiment 4 except that it further includes a material layer 511. A multilayer printed wiring board 513b in FIG. 5B is the same as Embodiment 4 except that it further includes an electromagnetic shielding layer 512. The multilayer printed wiring board of this embodiment has an effect comparable to that of the multilayer printed wiring boards of Embodiments 1 to 4.

As shown in FIGS. 5A and 5B, the multilayer printed wiring board 513b includes a plurality of first electrical insulating layers 503, a plurality of first wiring layers 514 arranged alternately with the first electrical insulating layers 503, and a plurality of first conductors 515 passing through each of the first electrical insulating layers 503 in their thickness direction for electrically connecting the first wiring layers 514. Each of the first wiring layers 514 includes first ground wiring 506 and first signal transmission wiring 504. The first conductors 515 include a first signal transmission conductor 502 electrically connected to the first signal transmission wiring 504 and a first ground conductor 505 electrically connected to the first ground wiring 506.

The side of the first electrical insulating layers 503 is coated with a first plating layer 507b, and the first plating layer 507b is electrically connected to the first ground wiring 506.

In the multilayer printed wiring board 513b, a circuit component built-in multilayer printed wiring board 513a is embedded in any of the first electrical insulating layers 503. Moreover, a first signal transmission conductor 502a is arranged in the edge portion of the first electrical insulating layer 503 (also referred to as a circuit component built-in layer 510) that contains the circuit component built-in multilayer printed wiring board 513a.

The multilayer printed wiring board 513b as shown in FIGS. 5A and 5B may have the following structure so that the impedance of the first signal transmission conductor 502a is matched to 50Ω. The material used for the first electrical insulating layer 503 and a second electrical insulating layer 503′ has a relative dielectric constant of, e.g., 3.8. The first signal transmission conductor 502a is an inner via with a diameter of, e.g., about 120 μm. The shortest distance between the first signal transmission conductor 502a and a second plating layer 507a is, e.g., about 0.25 mm. The shortest distance between the first signal transmission conductor 502a and the first plating layer 507b is, e.g., about 0.25 mm. The circuit component built-in layer 510 has a thickness of, e.g., 600 μm. The thickness of the other electrical insulating layers is, e.g., 100 μm.

In the circuit component built-in multilayer printed wiring board 513a, a second signal transmission conductor 502′a arranged in the edge portion of the second electrical insulating layer 503′ is an inner via with a diameter of, e.g., about 120 μm. The shortest distance between the second signal transmission conductor 502′a and a second ground conductor 505′a is, e.g., 0.25 mm. The shortest distance between the second signal transmission conductor 502′a and the second plating layer 507a is, e.g., 0.25 mm.

The first and second electrical insulating layers 503, 503′ can use the same material as that of the electrical insulating layer of the multilayer printed wiring board in Embodiment 1, e.g., a mixture of inorganic filler (90 wt %) and a resin composition that includes an epoxy resin and a curing agent.

In the multilayer printed wiring board 513b in FIG. 5A, a material. layer 511 is formed on the side of the first plating layer 507b that faces away from the first electrical insulating layer 503. Moreover, the material layer 511 also is formed on the side of the second plating layer 507a that faces away from the second electrical insulating layer 503′. The material layer 511 includes a material having a higher thermal conductivity than that of the material for the first and second electrical insulating layers 503, 503′. When the material layer 511 is used, heat dissipation of the multilayer printed wiring board 513b is improved to the extent that it can be expected to reduce the harmful effect of heat on a semiconductor. Therefore, the multilayer printed wiring board 513b can be applied easily to a heat-dissipating element (circuit component) such as a power circuit or the like.

In this embodiment, both of the first plating layer 507b and the second plating layer 507a are provided with the material layer. However, either of then may be provided with the material layer.

The material having a higher thermal conductivity may be, e.g., a mixture of an epoxy resin and alumina powder. The mixture includes, e.g., 95 wt % of alumina powder. The material layer 511 has a thickness of e.g., about 20 μm in view of high density, although the heat dissipation increases as the material layer 511 becomes thicker.

In the multilayer printed wiring board 513b in FIG. 5B, an electromagnetic shielding layer 512 is formed on the side of the first plating layer 507b that faces away from the first electrical insulting layer 503. Moreover, the electromagnetic shielding layer 512 also is formed on the side of the second plating layer 507a that faces away from the second electrical insulting layer 503′. The electromagnetic shielding layer 512 includes a magnetic material and a resin. The multilayer printed wiring board 513b in FIG. 5B further improves the EMI characteristics because of the electromagnetic shielding layer 512.

As the electromagnetic shielding layer 512, a material including, e.g., a resin composition that includes an epoxy resin and a curing agent (e.g., an amine-based curing agent or an acid anhydride-based curing agent) and ferrite powder (80 wt %) can be used. The ferrite power is a magnetic material with high thermal conductivity. When the content of ferrite power is not less than 30 wt %, and preferably not less than 50 wt %, high electromagnetic shielding and high heat dissipation can be ensured.

The thicker the electromagnetic shielding layer 512 is, the more the EMI characteristics improve. However, when the electromagnetic shielding layer 512 is too thick, it interferes with high density and increases the weight of the multilayer printed wiring board 513b. Therefore, the thickness of the electromagnetic shielding layer 512 is, e.g., 30 μm.

In the multilayer printed wiring board 513b in FIG. 5B, the deviation (error) of the impedance of the first signal transmission conductor 502a arranged in the edge portion of the circuit component built-in layer 510 from a predetermined value (50Ω) was not more than 1%, as with the case of the multilayer printed wiring board in Embodiment 4.

Moreover, the analysis showed that the EMI noise radiation of the multilayer printed wiring board 513b was reduced by about 6.5 dB compared with a conventional multilayer printed wiring board with a quasi-strip line structure (see FIG. 6B).

Like Embodiment 1, any general materials for a printed wiring board, e.g., a glass epoxy material or a material obtained by impregnating a reinforcing material that includes an organic material such as aramid fiber with a resin material can be used for the first and second electrical insulating layers 503, 503′.

The multilayer printed wiring board of this embodiment was produced by a method disclosed in JP 11(1999)-220262 A.

In the multilayer printed wiring boards of Embodiments 1 to 5, e.g., three ground conductors constitute the impedance control structure. However, the number of ground conductors is not limited thereto, and four or more ground conductors or at least one ground conductor may be used as long as the ground occupancy rate is not excessively high.

In the multilayer printed wiring boards of Embodiments 1 to 3, the plating layer and the ground conductor for constituting the impedance control structure are arranged symmetrically with respect to the central axis of the signal transmission conductor. However, the arrangement is not limited thereto. For example, the impedance of the signal transmission conductor arranged in the edge portion of the electrical insulating layer can be controlled by arranging the signal transmission conductor and the ground conductor in the indicated order in the direction from the plating layer to the center of the electrical insulating layer while appropriately setting the diameter of the signal transmission conductor, the distance between the plating layer and the signal transmission conductor, the distance between the signal transmission conductor and the ground conductor, or the like.

In the multilayer printed wiring boards of Embodiments 4 and 5, the first plating layer and the second plating layer are arranged symmetrically with respect to the central axis of the first signal transmission conductor. However, the arrangement is not limited thereto. For example, the impedance of the first signal transmission conductor arranged in the edge portion of the first electrical insulating layer can be controlled by arranging the first signal transmission conductor and the second plating layer in the indicated order in the direction from the first plating layer to the center of the first electrical insulating layer while appropriately setting the diameter of the first signal transmission conductor, the distance between the first plating layer and the first signal transmission conductor, the distance between the first signal transmission conductor and the second plating layer, or the like.

The invention may be embodied in other forms without departing from the spirit or essential characteristics thereof The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A multilayer printed wiring board comprising:
an electrical insulating layer;
a plurality of wiring layers arranged alternately with the electrical insulating layer, each of the wiring layers comprising ground wiring and signal transmission wiring;
a plurality of conductors passing through the electrical insulating layer in a thickness direction of the electrical insulating layer for electrically connecting the wiring layers, the conductors comprising a signal transmission conductor electrically connected to the signal transmission wiring and a ground conductor electrically connected to the ground wiring; and
a plating layer formed so as to cover a side of the electrical insulating layer and electrically connected to the ground wiring,
wherein impedance of the signal transmission conductor arranged in an edge portion of the electrical insulating layer is controlled by the ground conductor arranged opposite to the plating layer with said signal transmission conductor sandwiched therebetween and the plating layer.

2. The multilayer printed wiring board according to claim 1, further comprising a material layer that includes a material having a higher thermal conductivity than that of a material for the electrical insulating layer, and is formed on a side of the plating layer that faces away from the electrical insulating layer.

3. The multilayer printed wiring board according to claim 1, further comprising an electromagnetic shielding layer that includes a magnetic material and a resin, and is formed on a side of the plating layer that faces away from the electrical insulating layer.

4. A multilayer printed wiring board comprising:
an electrical insulating layer;
a plurality of wiring layers arranged alternately with the electrical insulating layer, each of the wiring layers comprising ground wiring and signal transmission wiring;
a plurality of conductors passing through the electrical insulating layer in a thickness direction of the electrical insulating layer for electrically connecting the wiring layers, the conductors comprising a signal transmission conductor electrically connected to the signal transmission wiring and a ground conductor electrically connected to the ground wiring;
a circuit component provided inside the electrical insulating layer; and
a plating layer formed so as to cover a side of the electrical insulating layer and electrically connected to the ground wiring,
wherein impedance of the signal transmission conductor arranged in an edge portion of the electrical insulating layer containing the circuit component is controlled by the ground conductor arranged opposite to the plating layer with said signal transmission conductor sandwiched therebetween and the plating layer.

5. The multilayer printed wiring board according to claim 4, further comprising a material layer that includes a material having a higher thermal conductivity than that of a material for the electrical insulating layer, and is formed on a side of the plating layer that faces away from the electrical insulating layer.

6. The multilayer printed wiring board according to claim 4, further comprising an electromagnetic shielding layer that includes a magnetic material and a resin, and is formed on a side of the plating layer that faces away from the electrical insulating layer.

7. A multilayer printed wiring board comprising:
a plurality of first electrical insulating layers;
a plurality of first wiring layers arranged alternately with the first electrical insulating layers, each of the first wiring layers comprising first ground wiring and first signal transmission wiring;
a plurality of first conductors passing through each of the first electrical insulating layers in a thickness direction of the first electrical insulating layers for electrically connecting the first wiring layers, the first conductors comprising a first signal transmission conductor electrically connected to the first signal transmission wiring and a first ground conductor electrically connected to the first ground wiring;
a circuit component built-in multilayer printed wiring board provided inside any of the first electrical insulating layers; and
a first plating layer formed so as to cover a side of the first electrical insulating layers and electrically connected to the first ground wiring,
wherein the circuit component built-in multilayer printed wiring board comprises:
a second electrical insulating layer;
a plurality of second wiring layers arranged alternately with the second electrical insulating layer, each of the second wiring layers comprising second ground wiring and second signal transmission wiring;
a plurality of second conductors passing through the second electrical insulating layer in a thickness direction of the second electrical insulating layer for electrically connecting the second wiring layers, the second conductors comprising a second signal transmission conductor electrically connected to the second signal transmission wiring and a second ground conductor electrically connected to the second ground wiring; and
a second plating layer formed so as to cover a side of the second electrical insulating layers and electrically connected to the second ground wiring, and
wherein impedance of the first signal transmission conductor arranged in an edge portion of the first electrical insulating layer containing the circuit component built-in multilayer printed wiring board is controlled by the second plating layer arranged opposite to the first plating layer with said first signal transmission conductor sandwiched therebetween and the first plating layer.

8. The multilayer printed wiring board according to claim 7, wherein the second signal transmission conductor is arranged in an edge portion of the second electrical insulating layer, and
the second ground conductor is arranged opposite to the second plating layer with said second signal transmission conductor sandwiched therebetween.

9. The multilayer printed wiring board according to claim 7, further comprising a material layer that includes a material having a higher thermal conductivity than that of a material for the first electrical insulating layer, and is formed on a side of the first plating layer that faces away from the first electrical insulating layer.

10. The multilayer printed wiring board according to claim 7, further comprising an electromagnetic shielding layer that includes a magnetic material and a resin, and is formed on a side of the first plating layer that faces away from the first electrical insulating layer.

11. An integrated circuit comprising the multilayer printed wiring board according to claim 1.

12. An integrated circuit comprising the multilayer printed wiring board according to claim 4.

13. An integrated circuit comprising the multilayer printed wiring board according to claim 7.
